(19) United States
(12) Patent Application Publication
(10) Pub. No.: US 2026/0028267 A1
(43) Pub. Date: Jan. 29, 2026

(54) GLASS

(71) Applicant: AGC Inc., Tokyo (JP)

(72) Inventors: Rikiya KADO, Tokyo (JP); Hirofumi TOKUNAGA, Tokyo (JP)

(73) Assignee: AGC Inc., Tokyo (JP)

(21) Appl. No.: 19/348,298

(22) Filed: Oct. 2, 2025

Related U.S. Application Data
(63) Continuation of application No. PCT/JP2024/015068, filed on Apr. 16, 2024.

(30) Foreign Application Priority Data
Apr. 17, 2023 (JP) 2023-067479

(51) Int. Cl. C03C 3/095; C03C 4/00; C03C 4/10; H01L 23/15

(52) U.S. Cl. CPC C03C 3/095; C03C 4/0085; C03C 4/10; H01L 23/15

(57) ABSTRACT

Manufacturing can be facilitated while deflection is suppressed. A glass (10) has a Young's modulus of 95 GPa or more, a coefficient of linear thermal expansion of 5.5 ppm/° C. or less, and a devitrification suppression parameter value represented by Formula (1) of 6.0 or more.

### CROSS-REFERENCE TO RELATED APPLICATION(S)

This application is a continuation of International Application No. PCT/JP2024/015068, filed on Apr. 16, 2024 which claims the benefit of priority of the prior Japanese Patent Application No. 2023-067479, filed on Apr. 17, 2023, the entire contents of which are incorporated herein by reference.

### BACKGROUND OF THE INVENTION

### 1. Field of the Invention

The present invention relates to glass.

### 2. Description of the Related Art

During manufacturing process of a semiconductor device, a glass may be used as a member for supporting the semiconductor device. For example, JP 2021-20840 A describes a supporting glass substrate having a high Young's modulus for suppressing deflection. In addition, the rate of thermal expansion may be lowered in order to suppress deflection due to the temperature change.

However, a glass having a low rate of thermal expansion and a high Young's modulus for suppressing deflection is likely to be crystallized and may be difficult to manufacture. Thus, there is a demand for a glass that is easy to manufacture while deflection is suppressed.

### SUMMARY OF THE INVENTION

It is an object of the present invention to at least partially solve the problems in the conventional technology.

A glass of the present disclosure has a Young's modulus of 95 GPa or more, a coefficient of linear thermal expansion of 5.5 ppm/° C. or less, and a devitrification suppression parameter value A represented by Formula (1) of 6.0 or more.

$$A = {\{ N \cdot ( - R \sum [ {R}_{x} {O}_{y} ] ln [ {R}_{x} {O}_{y} ] ) \}}^{0.4} \qquad ( 1 )$$

N is a number of oxides present in a content of 0.5% or more in terms of mol % on an oxide basis, among oxides contained in the glass, R is a gas constant, and [RₓO_{y}] is a content of oxide RₓO_{y} contained in the glass in terms of mol % on an oxide basis.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a schematic diagram of a glass according to the present embodiment; and

FIG. 2 is a schematic diagram for explaining a deflection evaluation.

### DETAILED DESCRIPTION OF THE PREFERRED EMBODIMENTS

Hereinafter, preferred embodiments of the present invention will be described in detail with reference to the accompanying drawings. Note that the present invention is not limited by the embodiments, and in a case where there are a plurality of embodiments, the present invention includes a combination of the embodiments. In addition, the numerical value includes the range of rounding. The upper limit and the lower limit of a numerical range can be appropriately combined.

### Glass

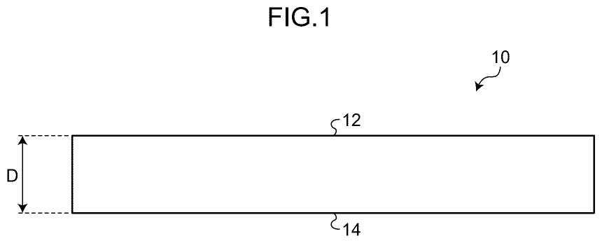

FIG. 1 is a schematic diagram of a glass according to the present embodiment. As illustrated in FIG. 1, the glass 10 according to the present embodiment is used as a glass substrate for manufacturing a semiconductor package, and more specifically, is a supporting glass substrate for manufacturing FOWLP or the like. However, the application of the glass 10 is not limited to the manufacture of FOWLP and the like and may be any application, and the glass 10 may be a glass substrate used for supporting a member or may be used for an application other than the support of a member. Note that FOWLP and the like encompass a fan out wafer level package (FOWLP) and a fan out panel level package (FOPLP).

### Young's Modulus of Glass

The Young's modulus of the glass 10 is 95 GPa or more, preferably 96 GPa or more, more preferably 97 GPa or more, more preferably 98 GPa or more, more preferably 99 GPa or more, more preferably 100 GPa or more, more preferably 101 GPa or more, more preferably 102 GPa or more, more preferably 103 GPa or more, more preferably 104 GPa or more, more preferably 105 GPa or more, more preferably 106 GPa or more, more preferably 108 GPa or more, more preferably 111 GPa or more, more preferably 112 GPa or more, more preferably 113 GPa or more, more preferably 114 GPa or more, and more preferably 115 GPa or more. In addition, the Young's modulus of the glass 10 is preferably 100 GPa or more and 150 GPa or less, more preferably 105 GPa or more and 140 GPa or less, and still more preferably 110 GPa or more and 130 GPa or less. When the Young's modulus falls within this range, deflection can be suppressed, and cutting, grinding, and polishing processing can be easily performed. The Young's modulus of the glass 10 can be measured based on propagation of an ultrasonic wave using 38DL PLUS manufactured by Olympus Corporation.

### Coefficient of Linear Thermal Expansion of Glass

The coefficient of linear thermal expansion of the glass 10 is 5.5 ppm/° C. or less, preferably 5.4 ppm/° C. or less, more preferably 5.3 ppm/° C. or less, more preferably 5.2 ppm/° C. or less, more preferably 5.1 ppm/° C. or less, more preferably 5.0 ppm/° C. or less, more preferably 4.9 ppm/° C. or less, more preferably 4.8 ppm/° C. or less, more preferably 4.7 ppm/° C. or less, more preferably 4.6 ppm/° C. or less, more preferably 4.5 ppm/° C. or less, more preferably 4.4 ppm/° C. or less, more preferably 4.3 ppm/° C. or less, more preferably 4.2 ppm/° C. or less, and more preferably 4.1 ppm/° C. or less. In addition, the coefficient of linear thermal expansion of the glass 10 is preferably 3.0 ppm/° C. or more and 5.5 ppm/° C. or less, more preferably 3.3 ppm/° C. or more and 5.0 ppm/° C. or less, and still more preferably 3.5 ppm/° C. or more and 4.5 ppm/° C. or less. When the coefficient of linear thermal expansion is low as described above, it is possible to suppress deflection due to the temperature change. That is, for example, in a case where the glass 10 supports a member having a low coefficient of thermal expansion, when the coefficient of linear thermal expansion of the glass 10 is also low as described above, it is possible to suppress deflection at the time of the temperature changes of the glass 10 and the member.

The coefficient of linear thermal expansion is an average coefficient of thermal expansion in the range of 50° C. to 200° C., and is a value measured in accordance with DIN-51045-1 as a standard for thermal expansion measurement. For example, measurement is performed in the range of 30 CC to 300° C. using a dilatometer DIL 402 Expedis Supreme manufactured by NETZSCH as a measuring apparatus, and an average coefficient of thermal expansion in the range of 50° C. to 200° C. may be employed as the coefficient of linear thermal expansion.

### Devitrification Suppression Parameter Value of Glass

The devitrification suppression parameter value A of the glass 10 is defined as a value represented by Formula (1).

$$A = {\{ N \cdot ( - R \sum [ {R}_{x} {O}_{y} ] ln [ {R}_{x} {O}_{y} ] ) \}}^{0.4} \qquad ( 1 )$$

N in Formula (1) is the number of oxides present in a content of 0.5% or more in terms of mol % on an oxide basis, among oxides contained in the glass 10. R is the gas constant, and R=8.31 (J·K⁻¹·mol⁻¹). [RₓO_{y}] is the content of the oxide RₓO_{y} contained in the glass 10 in terms of mol % on an oxide basis. R in RₓO_{y} is an element constituting the oxide, and x and y are any suitable integers.

Thus, for example, assuming that the glass 10 contains 30% of Na₂O and 70% of SiO₂ in terms of mol % on an oxide basis, the devitrification suppression parameter value A is 2·[{−R(0.3ln(0.3)+0.71n(0.7))}]^{0.4}, that is, about 2.53.

The devitrification suppression parameter value A is a parameter calculated based on the composition of the glass 10 as shown in Formula (1), and is an index indicating the difficulty of crystallization of the glass 10. For example, as N on the right side of Formula (1) is higher, the number of components contained in the glass 10 increases, and the components interfere with each other, so that the components tend to be less likely to be crystallized, and thus devitrification due to crystallization can be suppressed. In addition, for example, a term other than N on the right side of Formula (1) indicates the degree of disorder of the components, and as the value of the term is higher, the components tend to be more disordered and to be less likely to be crystallized, so that devitrification due to crystallization can be suppressed.

The devitrification suppression parameter value A of the glass 10 is 6.0 or more, preferably 6.2 or more, more preferably 6.25 or more, more preferably 6.3 or more, more preferably 6.5 or more, more preferably 6.7 or more, more preferably 6.9 or more, more preferably 7 or more, more preferably 7.7 or more, more preferably 7.9 or more, more preferably 8.1 or more, and more preferably 8.3 or more. In addition, the devitrification suppression parameter value A of the glass 10 is preferably 6.0 or more and 20 or less, more preferably 6.4 or more and 15 or less, and still more preferably 7.3 or more and 10 or less.

When the devitrification suppression parameter value A is high as described above, it is possible to prevent the liquidus temperature of the glass 10 from becoming too high. This makes it possible to keep the holding temperature for preventing the glass 10 from being crystallized low at the time of manufacturing the glass 10, and to facilitate manufacturing of the glass 10.

### Composition of Glass

Next, a preferred composition of the glass 10 will be described. However, the glass 10 may have any composition in which the Young's modulus, the coefficient of linear thermal expansion, and the devitrification suppression parameter value A satisfy the above ranges.

In the glass 10, the value E represented by Formula (2) is preferably 0.90 or more, more preferably 0.95 or more, still more preferably 1.00 or more, and still more preferably 1.05 or more. When the value E falls within this range, the Young's modulus is 95 GPa or more, and deflection can be appropriately suppressed.

$$( 2 )$$

$$E = ( 124 - 0.54 \times [ {SiO}_{2} ] + 0.29 \times [ {Al}_{2} {O}_{3} ] - 1.15 \times [ {B}_{2} {O}_{3} ] + 0.2 \times [ MgO ] - 0.2 \times [ CaO ] - 0.1 \times [ SrO ] - 1.2 \times [ BaO ] + 1. \times [ {Li}_{2} O ] - 3. \times [ {K}_{2} O ] + 0.05 \times [ ZnO ] + 1.45 \times [ {ZrO}_{2} ] - 0.05 \times [ {TiO}_{2} ] + 1.6 \times [ {Y}_{2} {O}_{3} ] + 1.35 \times [ {Gd}_{2} {O}_{3} ] + 1. \times [ {Ta}_{2} {O}_{5} ] ) / 100$$

In addition, in the glass 10, the value F represented by the following Formula (3) is preferably 1.05 or less, more preferably 1.0 or less, still more preferably 0.95 or less, and still more preferably 0.90 or less. When the value F falls within this range, the coefficient of thermal expansion is 5.5 ppm/K or less, and deflection can be suppressed.

$$( 3 )$$

$$F = ( 14.1 - 0.12 \times [ {SiO}_{2} ] - 0.13 \times [ {Al}_{2} {O}_{3} ] - 0.1 \times [ {B}_{2} {O}_{3} ] - 0.05 \times [ MgO ] + 0.01 \times [ CaO ] + 0.15 [ SrO ] + 0.02 \times [ BaO ] + 0.05 \times [ {Li}_{2} O ] - 0.07 \times [ ZnO ] - 0.03 * [ {ZrO}_{2} ] - 0.07 \times [ {TiO}_{2} ] + 0.04 \times [ {Y}_{2} {O}_{3} ] + 0.07 \times [ {Gd}_{2} {O}_{3} ] - 0.1 \times [ {Ta}_{2} {O}_{5} ] ) / 5.5$$

### SiO₂

The glass 10 preferably contains SiO₂ (the content of SiO₂ is higher than 0 mol %). SiO₂ is a component for decreasing the coefficient of linear thermal expansion and is a component for controlling the Young's modulus. In addition, in order to appropriately suppress increases in the melting temperature and the liquidus temperature, the content of SiO₂ is preferably 60% or less. In the glass 10, the content of SiO₂ is preferably 35% or more and 60% or less, more preferably 40% or more and 59% or less, more preferably 43% or more and 57% or less, more preferably 47% or more and 55% or less, more preferably 48% or more and 53% or less, more preferably 49% or more and 52% or less, and more preferably 50% or more and 51% or less as expressed in mol % on an oxide basis. When the content of SiO₂ falls within this range, the coefficient of linear thermal expansion can be reduced, and thus deflection can be suppressed. In addition, the devitrification suppression parameter value A can be increased, and thus manufacturing can be facilitated.

Al₂O₃

Al₂O₃ has effects of increasing the Young's modulus to suppress deflection and suppressing phase separation of glass. Thus, the glass 10 need not contain Al₂O₃ (the content of Al₂O₃ is 0 mol %), but may contain Al₂O₃. In addition, by adjusting the content of Al₂O₃ to 25% or less, an increase in the liquidus temperature can be suppressed. In the glass 10, the content of Al₂O₃ is preferably 5% or more and 25% or less, more preferably 6% or more and 20% or less, more preferably 8% or more and 19% or less, more preferably 10% or more and 18.5% or less, more preferably 11% or more and 18% or less, more preferably 12% or more and 17.5% or less, more preferably 13% or more and 17% or less, more preferably 14% or more and 16.5% or less, and more preferably 14.5% or more and 16% or less as expressed in mol % on an oxide basis. When the content of Al₂O₃ falls within this range, the coefficient of linear thermal expansion can be reduced while the Young's modulus is increased, and thus deflection can be suppressed. In addition, the devitrification suppression parameter value A can be increased, and thus manufacturing can be facilitated.

B₂O₃

B₂O₃ has effects of suppressing devitrification due to crystallization of glass to facilitate manufacturing and controlling the Young's modulus. Thus, the glass 10 need not contain B₂O₃ (the content of B₂O₃ is 0 mol %), but may contain B₂O₃. In the glass 10, the content of B₂O₃ is preferably 1% or more and 15% or less, more preferably 2% or more and 14% or less, more preferably 3% or more and 13% or less, more preferably 4% or more and 12% or less, more preferably 5% or more and 11% or less, and still more preferably 6% or more and 10% or less as expressed in mol % on an oxide basis. When the content of B₂O₃ falls within this range, the coefficient of linear thermal expansion can be reduced while the Young's modulus is increased, and thus deflection can be suppressed. In addition, the devitrification suppression parameter value A can be increased, and thus manufacturing can be facilitated.

### MgO

Since MgO increases the Young's modulus without increasing the density, deflection can be suppressed by increasing the specific modulus. In addition, there is also an effect of reducing the coefficient of linear thermal expansion. On the other hand, by adjusting the content of MgO to 28% or less, the liquidus temperature can be controlled to be low. Thus, the glass 10 need not contain MgO (the content of MgO is 0 mol %), but may contain MgO. In the glass 10, the content of MgO is preferably 13% or more and 28% or less, more preferably 14% or more and 27% or less, more preferably 17% or more and 25% or less, more preferably 18% or more and 23% or less, and still more preferably 20% or more and 22% or less as expressed in mol % on an oxide basis. When the content of MgO falls within this range, the coefficient of linear thermal expansion can be reduced while the Young's modulus is increased, and thus deflection can be suppressed. In addition, the devitrification suppression parameter value A can be increased, and thus manufacturing can be facilitated.

### CaO

CaO has characteristics of increasing the specific modulus next to MgO in the oxides of the group 2 elements, and not excessively decreasing the coefficient of linear thermal expansion, and further has a characteristic of being less likely to increase the liquidus temperature as compared with MgO. Thus, the glass 10 need not contain CaO (the content of CaO is 0 mol %), but may contain CaO. By adjusting the content of CaO to 10% or less, an increase in the coefficient of linear thermal expansion can be suppressed, and the liquidus temperature can be controlled to be low. In the glass 10, the content of CaO is preferably 0.5% or more and 10% or less, more preferably 1% or more and 8% or less, more preferably 2% or more and 5% or less, and still more preferably 3% or more and 4% or less as expressed in mol % on an oxide basis. When the content of CaO falls within this range, the coefficient of linear thermal expansion can be reduced while the Young's modulus is increased, and thus deflection can be suppressed. In addition, the devitrification suppression parameter value A can be increased, and thus manufacturing can be facilitated.

### SrO

SrO has effects of improving the meltability of glass and lowering the liquidus temperature. Thus, the glass 10 need not contain SrO (the content of SrO is 0 mol %), but may contain SrO. By adjusting the content of SrO to 10% or less, an increase in the coefficient of linear thermal expansion can be suppressed, and the liquidus temperature can be controlled to be low. In the glass 10, the content of SrO is preferably 0.5% or more and 10% or less, more preferably 1% or more and 8% or less, more preferably 2% or more and 5% or less, and still more preferably 3% or more and 4% or less as expressed in mol % on an oxide basis. When the content of SrO falls within this range, the coefficient of linear thermal expansion can be reduced while the Young's modulus is increased, and thus deflection can be suppressed. In addition, the devitrification suppression parameter value A can be increased, and thus manufacturing can be facilitated.

### BaO

BaO has effects of improving the meltability of glass and lowering the liquidus temperature. Thus, the glass 10 need not contain BaO (the content of BaO is 0 mol %), but may contain BaO. By adjusting the content of BaO to 10% or less, an increase in the coefficient of linear thermal expansion can be suppressed, and the liquidus temperature can be controlled to be low. In the glass 10, the content of BaO is preferably 0.5% or more and 10% or less, more preferably 1% or more and 8% or less, more preferably 2% or more and 5% or less, and still more preferably 3% or more and 4% or less as expressed in mol % on an oxide basis. When the content of BaO falls within this range, the coefficient of linear thermal expansion can be reduced while the Young's modulus is increased, and thus deflection can be suppressed. In addition, the devitrification suppression parameter value A can be increased, and thus manufacturing can be facilitated.

### Li₂O

Among alkali metal oxides, Li₂O has an effect of improving the meltability without decreasing the coefficient of linear thermal expansion. Thus, the glass 10 need not contain Li₂O (the content of Li₂O is 0 mol %), but may contain Li₂O. By adjusting the content of Li₂O to 5% or less, the Young's modulus can be increased, and an increase in the coefficient of linear thermal expansion can be suppressed. In the glass 10, the content of Li₂O is preferably 0.1% or more and 5% or less, more preferably 0.3% or more and 4% or less, more preferably 0.5% or more and 3% or less, more preferably 0.8% or more and 2.5% or less, and still more preferably 1% or more and 2% or less as expressed in mol % on an oxide basis. When the content of Li₂O falls within this range, the coefficient of linear thermal expansion can be reduced while the Young's modulus is increased, and thus deflection can be suppressed. In addition, the devitrification suppression parameter value A can be increased, and thus manufacturing can be facilitated.

### Na₂O

Among alkali metal oxides, Na₂O especially has effects of improving the meltability of glass and lowering the liquidus temperature. Thus, the glass 10 need not contain Na₂O (the content of Na₂O is 0 mol %), but may contain Na₂O. By adjusting the content of Na₂O to 5% or less, the Young's modulus can be increased, and an increase in the coefficient of linear thermal expansion can be suppressed. In the glass 10, the content of Na₂O is preferably 0.1% or more and 5% or less, more preferably 0.3% or more and 4% or less, more preferably 0.5% or more and 3% or less, more preferably 0.8% or more and 2.5% or less, and still more preferably 1% or more and 2% or less as expressed in mol % on an oxide basis. When the content of Na₂O falls within this range, the coefficient of linear thermal expansion can be reduced while the Young's modulus is increased, and thus deflection can be suppressed. In addition, the devitrification suppression parameter value A can be increased, and thus manufacturing can be facilitated.

### K₂O

K₂O has effects of improving the meltability of glass and lowering the liquidus temperature. Thus, the glass 10 need not contain K₂O (the content of K₂O is 0 mol %), but may contain K₂O. By adjusting the content of K₂O to 5% or less, the Young's modulus can be increased, and an increase in the coefficient of linear thermal expansion can be suppressed. In the glass 10, the content of K₂O is preferably 0.1% or more and 5% or less, more preferably 0.3% or more and 4% or less, more preferably 0.5% or more and 3% or less, more preferably 0.8% or more and 2.5% or less, and still more preferably 1% or more and 2% or less as expressed in mol % on an oxide basis. When the content of K₂O falls within this range, the coefficient of linear thermal expansion can be reduced while the Young's modulus is increased, and thus deflection can be suppressed. In addition, the devitrification suppression parameter value A can be increased, and thus manufacturing can be facilitated.

### ZnO

ZnO has effects of improving the meltability of glass and increasing the Young's modulus. Thus, the glass 10 need not contain ZnO (the content of ZnO is 0 mol %), but may contain ZnO. By adjusting the content of ZnO to 5% or less, an increase in the coefficient of linear thermal expansion can be suppressed, and the liquidus temperature can be controlled. In the glass 10, the content of ZnO is preferably 0.1% or more and 5% or less, more preferably 0.3% or more and 4% or less, more preferably 0.5% or more and 3% or less, more preferably 0.8% or more and 2.5% or less, and still more preferably 1% or more and 2% or less as expressed in mol % on an oxide basis. When the content of ZnO falls within this range, the coefficient of linear thermal expansion can be reduced while the Young's modulus is increased, and thus deflection can be suppressed. In addition, the devitrification suppression parameter value A can be increased, and thus manufacturing can be facilitated.

P₂O₅

P₂O₅ has effects of improving the meltability of glass and lowering the coefficient of linear thermal expansion. Thus, the glass 10 need not contain P₂O₅ (the content of P₂O₅ is 0 mol %), but may contain P₂O₅. By adjusting the content of P₂O₅ to 5% or less, the Young's modulus can be increased without deteriorating the chemical resistance, and an increase in the coefficient of linear thermal expansion can be suppressed. In the glass 10, the content of P₂O₅ is preferably 0.1% or more and 5% or less, more preferably 0.3% or more and 4% or less, more preferably 0.5% or more and 3% or less, more preferably 0.8% or more and 2.5% or less, and still more preferably 1% or more and 2% or less as expressed in mol % on an oxide basis. When the content of P₂O₅ falls within this range, the coefficient of linear thermal expansion can be reduced while the Young's modulus is increased, and thus deflection can be suppressed. In addition, the devitrification suppression parameter value A can be increased, and thus manufacturing can be facilitated.

### ZrO₂

ZrO₂ can increase the Young's modulus without relatively decreasing the coefficient of linear thermal expansion. Thus, the glass 10 need not contain ZrO₂ (the content of ZrO₂ is 0 mol %), but may contain ZrO₂. By adjusting the content of ZrO₂ to 5% or less, the liquidus temperature can be controlled. In the glass 10, the content of ZrO₂ is preferably 0.1% or more and 5% or less, more preferably 0.3% or more and 4% or less, more preferably 0.5% or more and 3% or less, more preferably 0.8% or more and 2.5% or less, and still more preferably 1% or more and 2% or less as expressed in mol % on an oxide basis. When the content of ZrO₂ falls within this range, the coefficient of linear thermal expansion can be reduced while the Young's modulus is increased, and thus deflection can be suppressed. In addition, the devitrification suppression parameter value A can be increased, and thus manufacturing can be facilitated.

### TiO₂

TiO₂ can increase the Young's modulus without relatively decreasing the coefficient of linear thermal expansion. Thus, the glass 10 need not contain TiO₂ (the content of TiO₂ is 0 mol %), but may contain TiO₂. By adjusting the content of TiO₂ to 5% or less, the liquidus temperature can be controlled. In the glass 10, the content of TiO₂ is preferably 0.1% or more and 5% or less, more preferably 0.3% or more and 4% or less, more preferably 0.5% or more and 3% or less, more preferably 0.8% or more and 2.5% or less, and still more preferably 1% or more and 2% or less as expressed in mol % on an oxide basis. When the content of TiO₂ falls within this range, the coefficient of linear thermal expansion can be reduced while the Young's modulus is increased, and thus deflection can be suppressed. In addition, the devitrification suppression parameter value A can be increased, and thus manufacturing can be facilitated.

Y₂O₃

Y₂O₃ has effects of improving the meltability of glass and increasing the Young's modulus. Thus, the glass 10 need not contain Y₂O₃ (the content of Y₂O₃ is 0 mol %), but may contain Y₂O₃. By adjusting the content of Y₂O₃ to 10% or less, the coefficient of linear thermal expansion can be controlled. In the glass 10, the content of Y₂O₃ is preferably 0.1% or more and 10% or less, more preferably 0.3% or more and 8% or less, more preferably 0.5% or more and 5% or less, more preferably 0.8% or more and 4% or less, more preferably 1% or more and 3% or less, and still more preferably 1% or more and 2% or less as expressed in mol % on an oxide basis. When the content of Y₂O₃ falls within this range, the coefficient of linear thermal expansion can be reduced while the Young's modulus is increased, and thus deflection can be suppressed. In addition, the devitrification suppression parameter value A can be increased, and thus manufacturing can be facilitated.

Gd₂O₃

Gd₂O₃ has effects of improving the meltability of glass and increasing the Young's modulus. Thus, the glass 10 need not contain Gd₂O₃ (the content of Gd₂O₃ is 0 mol %), but may contain Gd₂O₃. By adjusting the content of Gd₂O₃ to 10% or less, the coefficient of linear thermal expansion can be controlled. In the glass 10, the content of Gd₂O₃ is preferably 0.1% or more and 10% or less, more preferably 0.3% or more and 8% or less, more preferably 0.5% or more and 5% or less, more preferably 0.8% or more and 4% or less, more preferably 1% or more and 3% or less, and still more preferably 1% or more and 2% or less as expressed in mol % on an oxide basis. When the content of Gd₂O₃ falls within this range, the coefficient of linear thermal expansion can be reduced while the Young's modulus is increased, and thus deflection can be suppressed. In addition, the devitrification suppression parameter value A can be increased, and thus manufacturing can be facilitated.

### WO₃

WO₃ has effects of improving the meltability of glass and increasing the Young's modulus. Thus, the glass 10 need not contain WO₃ (the content of WO₃ is 0 mol %), but may contain WO₃. By adjusting the content of WO₃ to 5% or less, an increase in the coefficient of linear thermal expansion can be suppressed, and the liquidus temperature can be controlled. In the glass 10, the content of WO₃ is preferably 0.1% or more and 5% or less, more preferably 0.3% or more and 4% or less, more preferably 0.5% or more and 3% or less, more preferably 0.8% or more and 2.5% or less, and still more preferably 1% or more and 2% or less as expressed in mol % on an oxide basis. When the content of WO₃ falls within this range, the coefficient of linear thermal expansion can be reduced while the Young's modulus is increased, and thus deflection can be suppressed. In addition, the devitrification suppression parameter value A can be increased, and thus manufacturing can be facilitated.

Ta₂O₅

Ta₂O₅ has effects of decreasing the coefficient of linear thermal expansion and increasing the Young's modulus. Thus, the glass 10 need not contain Ta₂O₅ (the content of Ta₂O₅ is 0 mol %), but may contain Ta₂O₅. By adjusting the content of Ta₂O₅ to 10% or less, the liquidus temperature can be controlled. In the glass 10, the content of Ta₂O₅ is preferably 0.5% or more and 10% or less, more preferably 1% or more and 8% or less, more preferably 1.5% or more and 6% or less, more preferably 2% or more and 5% or less, more preferably 2.5% or more and 4.2% or less, and still more preferably 3% or more and 4% or less as expressed in mol % on an oxide basis. When the content of Ta₂O₅ falls within this range, the coefficient of linear thermal expansion can be reduced while the Young's modulus is increased, and thus deflection can be suppressed. In addition, the devitrification suppression parameter value A can be increased, and thus manufacturing can be facilitated.

Note that Ta₂O₅ is a component having a high degree of influence on the Young's modulus and the coefficient of linear thermal expansion.

In the glass 10, the content of Ta₂O₅ in terms of mol % on an oxide basis may be less than 0.5%. In this case, the glass 10 preferably has a Young's modulus of 105 GPa or more and a coefficient of linear thermal expansion of 5.1 ppm/K or less.

In the glass 10, the content of Ta₂O₅ in terms of mol % on an oxide basis may be 0.5% or more. In this case, the devitrification suppression parameter value A of the glass 10 is preferably 6.4 or more, more preferably 7.0 or more, and still more preferably 7.5 or more.

### MnO

MnO has an effect of increasing the Young's modulus. However, MnO may increase the liquidus temperature, and even a small amount of MnO causes the glass to be colored from dark brown to black. Thus, it is preferable that the glass 10 does not contain MnO. In the glass 10, the content of MnO is preferably 0.1% or less, more preferably 0.001% or more and 0.05% or less, and still more preferably 0.005% or more and 0.01% or less as expressed in mol % on an oxide basis. When the content of MnO falls within this range, a decrease in the light transmittance can be suppressed.

Fe₂O₃

The glass 10 preferably does not contain Fe₂O₃. In the glass 10, the content of Fe₂O₃ in outer percentage is preferably 0.1% or less, more preferably 0.001% or more and 0.05% or less, and still more preferably 0.005% or more and 0.01% or less as expressed in mass % on an oxide basis. When the content of Fe₂O₃ is low as described above, a decrease in the light transmittance can be suppressed. That is, for example, by adjusting the content of Fe₂O₃ within the above range, the transmittance for light with a wavelength of 900 nm through the glass 10 having a thickness of 0.7 mm can be 90% or more, and a decrease in the transmittance of infrared light can be suppressed.

Note that the content of Fe₂O₃ in outer percentage refers to the ratio of the mass of Fe₂O₃ contained in the glass 10 to the total value of the mass of all the components of the glass 10 excluding Fe₂O₃ on an oxide basis.

### Value of N

In the glass 10, the value of N (the number of oxides present in a content of 0.5% or more, among oxides contained in the glass 10) in Formula (1) is preferably 8 or more, more preferably 10 or more and 25 or less, more preferably 11 or more and 22 or less, more preferably 12 or more and 20 or less, more preferably 13 or more and 18 or less, and still more preferably 15 or more and 17 or less. When the number of N is high as described above, the devitrification suppression parameter value A can be increased, and thus manufacturing can be facilitated.

Note that the glass 10 preferably does not contain a sintered body. That is, the glass 10 is preferably a glass that is not a sintered body. Here, the sintered body refers to a member in which a plurality of particles are heated at a temperature lower than the melting point to bond the particles. The porosity of the sintered body is high to some extent because the sintered body includes voids, but the porosity of the glass 10 is low, and is usually 0% because the glass is not a sintered body. However, it is allowable to include an inevitable very small amount of pores. The porosity herein is a so-called true porosity, and refers to a value obtained by dividing a sum of volumes of pores (voids) communicating with the outside and pores (voids) not communicating with the outside by a total volume (apparent volume). The porosity can be measured according to, for example, JIS R 1634:1998 “Test methods for density and apparent porosity of fine ceramics”.

In addition, it is preferable that a glass used for the glass 10 is usually an amorphous glass, that is, an amorphous solid. Also, this glass may be a crystallized glass containing crystals on the surface or inside, but an amorphous glass is preferable from the viewpoint of density. Among ceramics, those produced by a sintering method are preferably not used because they have a low transmittance and a high density.

### Shape of Glass

Next, the shape of the glass 10 will be described. As illustrated in FIG. 1, the glass 10 is a plate-like glass substrate including a surface 12 which is a principal surface on one side and a surface 14 which is a principal surface opposite to the surface 12. The surface 14 may be, for example, parallel to the surface 12. The glass 10 may have a disk shape that is circular in plan view, that is, when viewed from a direction orthogonal to the surface 12, but the glass is not limited to the disk shape and may have any shape, and may be a plate of a polygonal shape such as a rectangle. Note that examples of the shape also include shapes in which a cut-out such as a notch or an orientation flat is provided on the outer periphery.

In addition, the thickness D of the glass 10, that is, the length between the surface 12 and the surface 14 is preferably 0.1 mm or more and 5.0 mm or less, more preferably 0.1 mm or more and 2.0 mm or less, and still more preferably 0.1 mm or more and 0.5 mm or more. By adjusting the thickness D to 0.1 mm or more, it is possible to prevent the glass 10 from becoming too thin and to suppress breakage due to deflection or impact. By adjusting the thickness D to 2.0 mm or less, it is possible to suppress the weight, and by adjusting the thickness D to 0.5 mm or less, it is possible to more suitably suppress the weight.

### Properties of Glass

Next, properties of the glass 10 will be described.

### Transmittance of Light

The internal transmittance for light with a wavelength of 350 nm (ultraviolet ray) through the glass 10 having a thickness D of 0.7 mm is preferably 30% or more, more preferably 35% or more, still more preferably 40% or more, still more preferably 45% or more, still more preferably 50% or more, still more preferably 55% or more, and still more preferably 60% or more. When the transmittance for light with a wavelength of 350 nm falls within this range, ultraviolet rays can be appropriately transmitted.

The internal transmittance for light with a wavelength of 1050 nm (infrared ray) through the glass 10 having a thickness D of 0.7 mm is preferably 80% or more, more preferably 85% or more, and still more preferably 90% or more. When the transmittance for light with a wavelength of 1050 nm falls within this range, infrared rays can be appropriately transmitted.

Note that the transmittance can be measured by measuring a spectral transmittance curve with a spectrophotometer or the like.

### Liquidus Temperature

The liquidus temperature of the glass 10 is preferably lower than 1400° C. In addition, the liquidus temperature of the glass 10 is more preferably 900° C. or higher and 1390° C. or lower, still more preferably 950° C. or higher and 1330° C. or lower, still more preferably 1000° C. or higher and 1300° C. or lower, and still more preferably 1050° C. or higher and 1250° C. or lower. In addition, the liquidus temperature of the glass 10 is preferably 1225° C. or lower, more preferably 1210° C. or lower, still more preferably 1185° C. or lower, still more preferably 1175° C. or lower, and still more preferably 1155° C. or lower. When the liquidus temperature is relatively low as described above, manufacturing can be facilitated. Note that the liquidus temperature can be evaluated by placing glass particles, which pass through a sieve with a mesh width of 4.0 mm and do not pass through a sieve with a mesh width of 2.3 mm, on a platinum dish, then holding the glass particles for 1 hour in an electric furnace set at a predetermined temperature, and measuring the temperature at which crystals are precipitated.

### Liquidus Viscosity

The liquidus viscosity log η_{L} (dPa·s) of the glass 10 is preferably 1 or more and 6 or less, more preferably 1.1 or more and 5 or less, more preferably 1.2 or more and 4.5 or less, and still more preferably 1.4 or more and 5 or less. In addition, the liquidus viscosity log η_{L} of the glass 10 is preferably 1.6 or more, more preferably 1.8 or more, still more preferably 1.9 or more, still more preferably 2.1 or more, still more preferably 2.3 or more, still more preferably 2.5 or more, still more preferably 2.8 or more, still more preferably 3 or more, still more preferably 3.15 or more, still more preferably 3.25 or more, and still more preferably 3.35 or more. The liquidus viscosity refers to the viscosity of the glass 10 at the liquidus temperature. When the liquidus viscosity is relatively high as described above, manufacturing can be facilitated. Note that the liquidus viscosity can be determined by measuring a temperature-viscosity curve according to an inner cylinder rotation method or the like and calculating the viscosity at the liquidus temperature.

### Fracture Toughness Value

The fracture toughness value K_{IC} of the glass 10 is preferably 0.88 MPa·m^{0.5} or more and 2.0 MPa·m^{0.5} or less, more preferably 0.90 MPa·m^{0.5} or more and 1.5 MPa·m_{0.5} or less, and still more preferably 1.0 MPa·m^{0.5} or more and 1.3 MPa·m^{0.5} or less. When the fracture toughness value K_{IC} falls within this range, breakage of the glass 10 can be suppressed. Note that the fracture toughness value K_{IC} can be measured using a single-edge-precracked-beam method (SEPB method) as defined in, for example, JIS R1607:2015 “Testing methods for fracture toughness of fine ceramics at room temperature”.

### Glass Transition Temperature

The glass transition temperature of the glass 10 is preferably 650° C. or higher and 800° C. or lower, more preferably 670° C. or higher and 775° C. or lower, and still more preferably 700° C. or higher and 750° C. or lower, and the glass transition temperature can be measured in accordance with the method defined in JIS R3103-3:2001 “Viscosity and viscometric fixed temperature of glass-Part 3: Determination of dilatometric transformation temperature”.

### Density

The density of the glass 10 is preferably 2.5 g/cm³ or more and 4.0 g/cm³ or less, more preferably 2.6 g/cm³ or more and 3.8 g/cm³ or less, still more preferably 2.7 g/cm³ or more and 3.5 g/cm³ or less, more preferably 2.8 g/cm³ or more and 3.3 g/cm³ or less, and still more preferably 2.9 g/cm³ or more and 3 g/cm³ or less.

### Method for Manufacturing Glass

The glass 10 may be manufactured by any method, but is manufactured, for example, by the following method. First, raw materials such as silica sand and soda ash, which are raw materials of the compounds contained in the glass 10, are melted by heating at a predetermined temperature (for example, 1500° C. to 1600° C.). Then, after the melted raw materials (glass) are clarified, a molding step of molding the glass into a plate shape is performed. The molded glass has the composition range of the glass 10 described above on an oxide basis. Then, a slow cooling step is performed on the glass molded in the molding step to manufacture glass 10.

Note that the method for manufacturing the glass 10 is not limited to the above, and may be any method. For example, the slow cooling step is not essential. In addition, various methods can be adopted as the molding step in manufacturing the glass 10, and examples thereof include a melt casting method, down-draw methods (for example, an overflow down-draw method, a slot down method, a redraw method, and the like), a float method, a roll-out method, and a press method.

Next, an example of a manufacturing step performed when the glass 10 is used for FOWLP manufacturing will be described. In the FOWLP manufacturing, a plurality of semiconductor chips are bonded onto the glass 10, and the semiconductor chips are covered with an encapsulant to form an element substrate. Then, the glass 10 and the element substrate are separated, and the opposite side of the element substrate from the semiconductor chips is bonded onto, for example, another glass 10. Then, wiring, solder bumps, and the like are formed on the semiconductor chips, and the element substrate and the glass 10 are separated again. Then, the element substrate is cut into pieces for each semiconductor chip, thereby obtaining a semiconductor device.

### Effects

As described above, a glass 10 according to a first aspect of the present disclosure has a Young's modulus of 95 GPa or more, a coefficient of linear thermal expansion of 5.5 ppm/° C. or less, and a devitrification suppression parameter value A represented by Formula (1) of 6.0 or more.

According to the present disclosure, deflection can be suppressed by setting the Young's modulus and the coefficient of linear thermal expansion within the above ranges. Here, the glass 10 having a high Young's modulus and a low coefficient of thermal expansion for suppressing deflection is particularly likely to be crystallized and may be difficult to manufacture. On this matter, in the present disclosure, by setting the devitrification suppression parameter value A within the above range, an increase in the liquidus temperature can be suppressed, and thus manufacturing can be facilitated.

A glass 10 according to a second aspect of the present disclosure is the glass 10 according to the first aspect, and preferably has a content of Ta₂O of less than 0.5%. According to the present disclosure, manufacturing can be facilitated while deflection is suppressed.

A glass 10 according to a third aspect of the present disclosure is the glass 10 according to the second aspect, and preferably has a Young's modulus of 105 GPa or more and a coefficient of linear thermal expansion of 5.1 ppm/° C. or less. According to the present disclosure, manufacturing can be facilitated while deflection is suppressed.

A glass 10 according to a fourth aspect of the present disclosure is the glass 10 according to the first aspect, and preferably has a content of Ta₂O₅ in terms of mol % on an oxide basis of 0.5% or more, and a devitrification suppression parameter value A of 6.4 or more. According to the present disclosure, manufacturing can be facilitated while deflection is suppressed.

A glass 10 according to a fifth aspect of the present disclosure is the glass 10 according to any one of the first to fourth aspects, and preferably contains
SiO₂: 35% to 60%,
Al₂O₃: 6% to 20%, and
MgO: 13% to 28%,
as expressed in mol % on an oxide basis. When the content of each component falls within this range, the Young's modulus is 95 GPa or more, the coefficient of linear thermal expansion is 5.5 ppm/° C. or less, and thus deflection can be suppressed. Note that the numerical range represented by “to” means a numerical range including numerical values before and after “to” as a lower limit value and an upper limit value, and when “to” is used in the following description, the same meaning is given.

A glass 10 according to a sixth aspect of the present disclosure is the glass 10 according to any one of the first to fifth aspects, and preferably has a transmittance of light with a wavelength of 350 nm at a thickness of 0.7 mm of 30% or more. According to the present disclosure, ultraviolet rays can be appropriately transmitted.

A glass 10 according to a seventh aspect of the present disclosure is the glass 10 according to any one of the first to sixth aspects, and preferably has a transmittance of light with a wavelength of 1050 nm at a thickness of 0.7 mm of 80% or more. According to the present disclosure, infrared rays can be appropriately transmitted.

A glass 10 according to an eighth aspect of the present disclosure is the glass 10 according to any one of the first to seventh aspects, and N is preferably 8 or more. According to the present disclosure, when the number of N is high as described above, the devitrification suppression parameter value A can be increased, and thus manufacturing can be facilitated.

A glass 10 according to a ninth aspect of the present disclosure is the glass 10 according to any one of the first to eighth aspects, and is preferably used as a substrate. The glass 10 of the present disclosure is suitably used for a substrate.

A glass 10 according to a tenth aspect of the present disclosure is the glass 10 according to the ninth aspect, and is preferably used in manufacture of at least one of a fan out wafer level package or a fan out panel level package. The glass 10 is suitably used for these applications.

### EXAMPLES

Next, examples will be described. Tables 1 to 5 are tables showing properties of the glass of each example. Note that the embodiment may be changed as long as the effects of the invention are obtained.

TABLE 1

| | Exam- | Exam- | Exam- | Exam- | Exam- | Exam- | Exam- | Exam- | Exam- | Exam- |
|---|---|---|---|---|---|---|---|---|---|---|
| mol % | ple 1 | ple 2 | ple 3 | ple 4 | ple 5 | ple 6 | ple 7 | ple 8 | ple 9 | ple 10 |
| SiO₂ | 47.9 | 51 | 45 | 49 | 49 | 54 | 43 | 45 | 48 | 47.8 |
| Al₂O₃ | 17.1 | 17.1 | 16.9 | 12 | 12 | 10 | 18 | 20 | 10 | 12.2 |
| B₂O₃ | 2.3 | 2.3 | 2.6 | 5 | 5 | 3 | 2.5 | 4 | 7 | 4.6 |
| MgO | 20.3 | 17.2 | 20 | 21 | 21 | 18 | 20.3 | 21 | 22 | 26.2 |
| CaO | 1 | 1 | 1 | 1 | 1 | 1 | 1 | 3 | 3 | 1 |
| SrO | 0.1 | 1 | 1 | 1 | 1 | 1 | 1 | 2 | 3 | 1 |
| BaO | 1 | 0.1 | 1 | 1 | 1 | 1 | 0.5 | | 3 | 1 |
| Li₂O | 1 | 1 | 1 | 1 | 1 | 1 | 1 | | | 1 |
| Na₂O | 0.1 | 0.1 | | | | | 0.1 | | | 0.1 |
| K₂O | 0.1 | 0.1 | | | | | 0.1 | | | 0.1 |
| ZnO | 1 | 1 | 1 | 1 | 1 | 1 | 0.5 | | | 1 |
| P₂O₅ | | | 1 | | | | | | | |
| ZrO₂ | 1 | 1 | 2 | 1 | 1 | 2 | 1 | 2 | 1 | 1 |
| TiO₂ | 1 | 1 | 1 | 1 | 1 | 2 | 1 | | 1 | 1 |
| Y₂O₃ | 1 | 1 | 1 | 1 | 1 | 1 | 1 | | 1 | 1 |
| Gd₂O₃ | 0.9 | 0.9 | 1 | 1 | 1 | 1 | 1 | | | 1 |
| WO₃ | | | | 2 | | 2 | | | | |
| Ta₂O₅ | 4.2 | 4.2 | 4.5 | 2 | 4 | 2 | 8 | 3 | 1 | |
| Glass transition | 744 | 747 | 738 | 707 | 717 | 716 | 745 | 750 | 708 | 707 |
| point (° C.) | | | | | | | | | | |
| Density (g/cm³) | 3.33 | 3.30 | 3.45 | 3.20 | 3.31 | 3.21 | 3.74 | 3.086 | 2.97 | 2.91 |
| Young's | 113 | 111 | 114 | 103 | 106 | 102 | 119 | 108 | 97 | 106 |
| modulus (GPa) | | | | | | | | | | |
| CTE (ppm/° C.) | 4.26 | 4.06 | 4.53 | 4.54 | 4.63 | 4.54 | 4.42 | 4.1 | 4.96 | 4.9 |
| Liquidus | 1285 | 1295 | 1325 | 1265 | 1305 | 1295 | 1390 | 1350 | 1165 | 1210 |
| temperature (° C.) | | | | | | | | | | |
| Liquidus viscosity | 2.19 | 2.38 | 1.81 | 2.1 | 1.86 | 2.35 | 1.48 | 1.87 | 3.17 | 2.6 |
| log η_{L} (dPa · s) | | | | | | | | | | |
| KIC (MPa · m^{0.5}) | 0.9< | 0.99 | 0.9< | 0.8< | 0.9< | 0.8< | 0.9< | 0.99 | 0.8< | 0.93 |
| Number of | 13 | 13 | 15 | 15 | 14 | 15 | 14 | 8 | 11 | 13 |
| components, N | | | | | | | | | | |
| Devitrification | 7.82 | 7.76 | 8.54 | 8.42 | 8.14 | 8.34 | 8.25 | 6.31 | 7.35 | 7.71 |
| suppression | | | | | | | | | | |
| parameter | | | | | | | | | | |
| value A | | | | | | | | | | |
| Transmittance | 50< | 50< | 50< | 50< | 50< | 50< | 50< | 50< | 50< | 50< |
| (%) @ | | | | | | | | | | |
| 350 nm, | | | | | | | | | | |
| 0.7 mmt | | | | | | | | | | |
| Transmittance | 90< | 90< | 90< | 90< | 90< | 90< | 90< | 90< | 90< | 90< |
| (%) @ | | | | | | | | | | |
| 1050 nm, | | | | | | | | | | |
| 0.7 mmt | | | | | | | | | | |
| Deflection | ⊚ | ⊚ | ⊚ | ⊚ | ⊚ | ⊚ | ⊚ | ⊚ | ⊚ | ⊚ |
| determination | | | | | | | | | | |
| Manufacturability | ◯ | ◯ | ◯ | ◯ | ◯ | ◯ | ◯ | ◯ | ◯ | ◯ |
| determination | | | | | | | | | | |

TABLE 2

| | Exam- | Exam- | Exam- | Exam- | Exam- | Exam- | Exam- | Exam- | Exam- | Exam- |
|---|---|---|---|---|---|---|---|---|---|---|
| mol % | ple 11 | ple 12 | ple 13 | ple 14 | ple 15 | ple 16 | ple 17 | ple 18 | ple 19 | ple 20 |
| SiO₂ | 50 | 49.8 | 48 | 50.7 | 47.2 | 47.2 | 56.5 | 60.5 | 50 | 52 |
| Al₂O₃ | 13 | 12.2 | 12 | 18.1 | 20 | 18 | 20 | 14 | 10 | 11 |
| B₂O₃ | 4.4 | 3.6 | 7 | 2.4 | 2.4 | 2.4 | | | 6 | 5 |
| MgO | 22.4 | 24.2 | 22 | 21.4 | 22.1 | 22.1 | 14.3 | 18.3 | 22 | 18 |
| CaO | 2 | 1 | 1 | 1 | 1 | 1 | 1 | 1 | 2 | 2 |
| SrO | 1 | 1 | 1 | 1 | 1 | 0.1 | 1 | | 2 | 3 |
| BaO | 2 | 1 | 1 | 0.1 | 0.1 | 1 | 1 | | 4 | 4 |
| Li₂O | 1 | 1 | 1 | 1 | 1 | 1 | 1 | 1 | | |
| Na₂O | 0.1 | 0.1 | 1 | 0.1 | 0.1 | 0.1 | 0.1 | 0.1 | | |
| K₂O | 0.1 | 0.1 | 1 | 0.1 | 0.1 | 0.1 | 0.1 | 0.1 | | |
| ZnO | 1 | 1 | 1 | 0.1 | 1 | 3 | 1 | 1 | | |
| P₂O₅ | 1 | 1 | | | | | | | | |
| ZrO₂ | 1 | 1 | 1 | 1 | 1 | 1 | 1 | 1 | 1 | 1 |
| TiO₂ | 1 | 1 | 1 | 1 | 1 | 1 | 1 | 1 | 1 | 1 |
| Y₂O₃ | | 1 | 1 | 1 | 1 | 1 | 1 | 1 | 2 | 3 |
| Gd₂O₃ | | 1 | 1 | 1 | 1 | 1 | 1 | 1 | | |
| WO₃ | | | | | | | | | | |
| Ta₂O₅ | | | | | | | | | | |
| Glass transition | 708 | 714 | 678 | 746 | 747 | 733 | 773 | 758 | 722 | 732 |
| point (° C.) | | | | | | | | | | |
| Density (g/cm³) | 2.74 | 2.89 | 2.85 | 2.84 | 2.88 | 2.94 | 2.85 | 2.78 | 2.91 | 2.99 |
| Young's | 100 | 104 | 99.1 | 108 | 111 | 111 | 105.9 | 103.2 | 97 | 97 |
| modulus (GPa) | | | | | | | | | | |
| CTE (ppm/° C.) | 4.48 | 4.74 | 5.2 | 4.24 | 4.35 | 4.48 | 3.84 | 3.81 | 5.06 | 5.16 |
| Liquidus | 1245 | 1225 | 1175 | 1315 | 1320 | 1350 | 1390 | 1390 | 1190 | 1230 |
| temperature (° C.) | | | | | | | | | | |
| Liquidus viscosity | 2.33 | 2.67 | 2.83 | 2.15 | 1.93 | 1.9 | 2.75 | 2.81 | 2.86 | 2.66 |
| log η_{L} (dPa · s) | | | | | | | | | | |
| KIC (MPa · m^{0.5}) | 0.8< | 0.9 | 0.91 | 0.9< | 1.0 | 1.01 | 0.9< | 0.9< | 0.8< | 0.8< |
| Number of | 12 | 14 | 15 | 11 | 12 | 12 | 12 | 10 | 10 | 10 |
| components, N | | | | | | | | | | |
| Devitrification | 7.47 | 7.97 | 8.38 | 7.01 | 7.39 | 7.48 | 7.11 | 6.36 | 6.95 | 6.98 |
| suppression | | | | | | | | | | |
| parameter | | | | | | | | | | |
| value A | | | | | | | | | | |
| Transmittance | 50< | 50< | 50< | 50< | 50< | 50< | 50< | 50< | 50< | 50< |
| (%) @ | | | | | | | | | | |
| 350 nm, | | | | | | | | | | |
| 0.7 mmt | | | | | | | | | | |
| Transmittance | 90< | 90< | 90< | 90< | 90< | 90< | 90< | 90< | 90< | 90< |
| (%) @ | | | | | | | | | | |
| 1050 nm, | | | | | | | | | | |
| 0.7 mmt | | | | | | | | | | |
| Deflection | ⊚ | ⊚ | ⊚ | ⊚ | ⊚ | ⊚ | ⊚ | ⊚ | ⊚ | ⊚ |
| determination | | | | | | | | | | |
| Manufacturability | ◯ | ◯ | ◯ | ◯ | ◯ | ◯ | ◯ | ◯ | ◯ | ◯ |
| determination | | | | | | | | | | |

TABLE 3

| | Exam- | Exam- | Exam- | Exam- | Exam- | Exam- | Exam- | Exam- | Exam- | Exam- |
|---|---|---|---|---|---|---|---|---|---|---|
| mol % | ple 21 | ple 22 | ple 23 | ple 24 | ple 25 | ple 26 | ple 27 | ple 28 | ple 29 | ple 30 |
| SiO₂ | 48 | 49 | 50 | 49 | 49 | 48 | 48 | 48 | 47 | 48 |
| Al₂O₃ | 12 | 12 | 12 | 13 | 12 | 12 | 11 | 12 | 12 | 11 |
| B₂O₃ | 7 | 7 | 7 | 7 | 7 | 7 | 7 | 7 | 9 | 7 |
| MgO | 22 | 22 | 22 | 23 | 22 | 22 | 22 | 20 | 22 | 22 |
| CaO | 2 | 2 | 2 | 2 | 2 | 2 | 3 | 3 | 2 | 3 |
| SrO | 2 | 2 | 2 | 2 | 2 | 3 | 3 | 3 | 2 | 3 |
| BaO | 2 | 2 | 2 | 2 | 2 | 2 | 3 | 3 | 2 | 3 |
| Li₂O | 1 | | | | | | | | | |
| Na₂O | | | | | | | | | | |
| K₂O | | | | | | | | | | |
| ZnO | | | | | | | | | | |
| P₂O₅ | | | | | | | | | | |
| ZrO₂ | 1 | 1 | 1 | 1 | 2 | 1 | 1 | 1 | 1 | 1 |
| TiO₂ | 1 | 1 | 1 | 1 | 2 | 1 | 1 | 1 | 1 | |
| Y₂O₃ | 1 | 1 | 1 | | | 2 | 1 | 2 | 2 | 2 |
| Gd₂O₃ | 1 | 1 | | | | | | | | |
| WO₃ | | | | | | | | | | |
| Ta₂O₅ | | | | | | | | | | |
| Glass transition | 697 | 725 | 724 | 722 | 727 | 718 | 710 | 718 | 717 | 709 |
| point (° C.) | | | | | | | | | | |
| Density (g/cm³) | 2.9 | 2.89 | 2.78 | 2.72 | 2.75 | 2.87 | 2.85 | 2.9 | 2.82 | 2.908 |
| Young's | 101 | 98 | 96 | 95 | 96 | 99 | 96 | 98 | 98 | 98 |
| modulus (GPa) | | | | | | | | | | |
| CTE (ppm/° C.) | 4.95 | 4.76 | 4.52 | 4.41 | 4.48 | 4.9 | 5.01 | 5 | 4.68 | 5.14 |
| Liquidus | 1155 | 1150 | 1185 | 1215 | 1330 | 1155 | 1175 | 1155 | 1130 | 1155 |
| temperature (° C.) | | | | | | | | | | |
| Liquidus viscosity | 3.17 | 3.32 | 3.15 | 2.90 | 1.89 | 3.27 | 3.08 | 3.27 | 3.52 | 3.24 |
| log η_{L} (dPa · s) | | | | | | | | | | |
| KIC (MPa · m^{0.5}) | 0.8< | 0.8< | 0.8< | 0.8< | 0.8< | 0.8< | 0.8< | 0.8< | 0.8< | 0.8< |
| Number of | 12 | 11 | 10 | 9 | 9 | 10 | 10 | 10 | 10 | 9 |
| components, N | | | | | | | | | | |
| Devitrification | 7.59 | 7.24 | 6.88 | 6.55 | 6.63 | 7.00 | 7.01 | 7.07 | 7.01 | 6.70 |
| suppression | | | | | | | | | | |
| parameter | | | | | | | | | | |
| value A | | | | | | | | | | |
| Transmittance | 50< | 50< | 50< | 50< | 50< | 50< | 50< | 50< | 50< | 50< |
| (%) @ | | | | | | | | | | |
| 350 nm, | | | | | | | | | | |
| 0.7 mmt | | | | | | | | | | |
| Transmittance | 90< | 90< | 90< | 90< | 90< | 90< | 90< | 90< | 90< | 90< |
| (%) @ | | | | | | | | | | |
| 1050 nm, | | | | | | | | | | |
| 0.7 mmt | | | | | | | | | | |
| Deflection | ⊚ | ⊚ | ⊚ | ⊚ | ⊚ | ⊚ | ⊚ | ⊚ | ⊚ | ⊚ |
| determination | | | | | | | | | | |
| Manufacturability | ◯ | ◯ | ◯ | ◯ | ◯ | ◯ | ◯ | ◯ | ◯ | ◯ |
| determination | | | | | | | | | | |

TABLE 4

| | Exam- | Exam- | Exam- | Exam- | Exam- | Exam- |
|---|---|---|---|---|---|---|
| mol % | ple 31 | ple 32 | ple 33 | ple 34 | ple 35 | ple 36 |
| SiO₂ | 48 | 51 | 50 | 52 | 50 | 54.7 |
| Al₂O₃ | 12 | 12 | 11 | 11 | 11 | 6.0 |
| B₂O₃ | 7 | 5 | 6 | 3 | 5 | 5.0 |
| MgO | 22 | 20 | 22 | 22 | 22 | 21.9 |
| CaO | 3 | 3 | 3 | 3 | 1 | 3.0 |
| SrO | 3 | 3 | 3 | 3 | 2 | 3.0 |
| BaO | 3 | 3 | 2 | 2 | 4 | 2.0 |
| Li₂O | | | | | | |
| Na₂O | | | | | | |
| K₂O | | | | | | |
| ZnO | | | | | | |
| P₂O₅ | | | | | | |
| ZrO₂ | | | 0.5 | 1 | 2.3 | 2.3 |
| TiO₂ | | | 0.5 | 1 | 1.5 | 1.5 |
| Y₂O₃ | 2 | 3 | 2 | 2 | 1.1 | 0.7 |
| Gd₂O₃ | | | | | | |
| WO₃ | | | | | | |
| Ta₂O₅ | | | | | | |
| Glass transition | 709 | 724 | 716 | 731 | 736 | 715 |
| point (° C.) | | | | | | |
| Density (g/cm³) | 2.88 | 2.94 | 2.91 | 2.91 | 2.92 | 2.83 |
| Young's | 97 | 99 | 97 | 101 | 98 | 95 |
| modulus (GPa) | | | | | | |
| CTE (ppm/° C.) | 5.08 | 5.04 | 5.06 | 4.97 | 4.86 | 4.88 |
| Liquidus | 1175 | 1185 | 1185 | 1210 | 1283 | 1183 |
| temperature (° C.) | | | | | | |
| Liquidus viscosity | 3.26 | 3.35 | 3.17 | 2.92 | 2.30 | 2.82 |
| log η_{L} (dPa · s) | | | | | | |
| KIC (MPa · m^{0.5}) | 0.8< | 0.8< | 0.8< | 0.8< | 0.8< | 0.8< |
| Number of | 8 | 8 | 10 | 10 | 10 | 10 |
| components, N | | | | | | |
| Devitrification | 6.34 | 6.29 | 6.91 | 6.85 | 6.94 | 6.80 |
| suppression | | | | | | |
| parameter | | | | | | |
| value A | | | | | | |
| Transmittance | 50< | 50< | 50< | 50< | 50< | 50< |
| (%) @ | | | | | | |
| 350 nm, | | | | | | |
| 0.7 mmt | | | | | | |
| Transmittance | 90< | 90< | 90< | 90< | 90< | 90< |
| (%) @ | | | | | | |
| 1050 nm, | | | | | | |
| 0.7 mmt | | | | | | |
| Deflection | ⊚ | ⊚ | ⊚ | ⊚ | ⊚ | ⊚ |
| determination | | | | | | |
| Manufacturability | ◯ | ◯ | ◯ | ◯ | ◯ | ◯ |
| determination | | | | | | |

TABLE 5

| | Exam- | Exam- | Exam- | Exam- | Exam- | Exam- | Exam- | Exam- | Exam- | Exam- | Exam- |
|---|---|---|---|---|---|---|---|---|---|---|---|
| mol % | ple 37 | ple 38 | ple 39 | ple 40 | ple 41 | ple 42 | ple 43 | ple 44 | ple 45 | ple 46 | ple 47 |
| SiO₂ | 45 | 42 | 45.3 | 50 | 50 | 45.7 | 68.5 | 30 | 57 | 67 | 66 |
| Al₂O₃ | 19 | 22.9 | 21.9 | 25 | 20 | 13.9 | 12.6 | 30 | 18.5 | 8 | 11 |
| B₂O₃ | 2.8 | 2.8 | 2.8 | | 10 | 4.5 | | 10 | 2 | 6 | 8 |
| MgO | 22.2 | 25.3 | 23.3 | 25 | | 34.4 | 10.6 | 24 | 19.5 | 3.5 | 5 |
| CaO | 5 | | 0.1 | | | | 8.2 | | 2.2 | 4 | 5 |
| SrO | | | 0.1 | | | | 1.5 | | | 4.5 | 5 |
| BaO | | | 0.1 | | | | 3 | | | 7 | |
| Li₂O | | | 0.1 | | | | | | | | |
| Na₂O | | | 0.1 | | | | | | | | |
| K₂O | | | 0.1 | | | | | | | | |
| ZnO | | | 0.1 | | | | | | | | |
| P₂O₅ | | | | | | | | | | | |
| ZrO₂ | | 4.1 | 1 | | | | | 3 | 0.5 | | |
| TiO₂ | | 0.2 | 1 | | | 1.5 | | 3 | 0.3 | | |
| Y₂O₃ | | | | | 20 | | | | | | |
| Gd₂O₃ | | | | | | | | | | | |
| WO₃ | | | | | | | | | | | |
| Ta₂O₅ | 6 | 2.7 | 4 | | | | | | | | |
| Glass transition | 762 | 780 | 771 | 812 | 819 | 764 | 767 | 754 | 786 | 690 | 710 |
| point (° C.) | | | | | | | | | | | |
| Density (g/cm³) | 3.32 | 3.152 | 3.15 | 2.68 | 3.44 | 2.67 | 2.6 | 2.8 | 2.59 | 2.77 | 2.51 |
| Young's | 113 | 119 | 113 | 110 | 118 | 108 | 94 | 117 | 101 | 75.8 | 76 |
| modulus (GPa) | | | | | | | | | | | |
| CTE (ppm/° C.) | 3.5 | 4 | 3.83 | 3.8 | 5 | 3.6 | 3.57 | 4.14 | 3.37 | 4.83 | 3.63 |
| Liquidus | 1425 | 1425 | 1400 | 1400 | 1400 | 1440 | 1400 | 1400 | 1400 | 1255 | 1265 |
| temperature (° C.) | | | | | | | | | | | |
| Liquidus viscosity | 1.25 | 1.25 | 1.68 | | 2.65 | 1.7 | 0.54 | 2.34 | 2.01 | 3.81 | 4.11 |
| log η_{L} (dPa · s) | | | | | | | | | | | |
| KIC (MPa · m^{0.5}) | 0.9< | 0.9< | 0.9< | 0.9< | 0.8< | 0.9< | 0.8< | 0.9< | 0.8< | 0.7< | 0.7< |
| Number of | 6 | 6 | 7 | 3 | 4 | 5 | 6 | 6 | 6 | 7 | 6 |
| components, N | | | | | | | | | | | |
| Devitrification | 5.51 | 5.45 | 5.81 | 3.68 | 4.40 | 4.78 | 5.02 | 5.63 | 5.06 | 5.49 | 5.08 |
| suppression | | | | | | | | | | | |
| parameter | | | | | | | | | | | |
| value A | | | | | | | | | | | |
| Transmittance | 50< | 50< | 50< | 50< | 50< | 50< | 50< | 50< | 50< | 50< | 50< |
| (%) @ | | | | | | | | | | | |
| 350 nm, | | | | | | | | | | | |
| 0.7 mmt | | | | | | | | | | | |
| Transmittance | 90< | 90< | 90< | 90< | 90< | 90< | 90< | 90< | 90< | 90< | 90< |
| (%) @ | | | | | | | | | | | |
| 1050 nm, | | | | | | | | | | | |
| 0.7 mmt | | | | | | | | | | | |
| Deflection | X | ⊚ | ⊚ | ⊚ | ⊚ | X | X | ⊚ | X | X | X |
| determination | | | | | | | | | | | |
| Manufacturability | X | X | X | X | X | X | X | X | X | X | X |
| determination | | | | | | | | | | | |

### Example 1

In Example 1, a glass having the composition shown in Table 1 was produced. In Example 1, a base plate having a diameter of 320 mm and a thickness of 6 mm was manufactured using a melt casting method. Next, a plurality of plates having a diameter of 300 mm and a thickness of 3 mm were cut out from the center of the base plate. Both surfaces of these plates were polished using cerium oxide as a polishing material to obtain a glass having a thickness of 0.7 mm.

For the glass of Example 1, the glass transition temperature (° C.) was measured. The glass transition temperature was measured by obtaining an expansion curve until the glass was softened using a thermal expansion measuring apparatus.

For the glass of Example 1, the density (g/cm³) was measured. The density was measured by the Archimedes method.

For the glass of Example 1, the Young's modulus was measured. The Young's modulus was measured based on propagation of an ultrasonic wave using 38DL PLUS manufactured by Olympus Corporation.

For the glass of Example 1, the coefficient of linear thermal expansion CTE (ppm/° C.) was measured. Measurement was performed in the range of 30° C. to 300° C. using a dilatometer (DIL 402 Expedis Supreme) manufactured by NETZSCH as a measuring apparatus, and an average coefficient of thermal expansion in the range of 50° C. to 200° C. was defined as the coefficient of linear thermal expansion CTE.

For the glass of Example 1, the liquidus temperature (° C.) was measured. The liquidus temperature was measured by placing glass particles, which passed through a sieve with a mesh width of 4.0 mm and did not pass through a sieve with a mesh width of 2.3 mm, on a platinum dish, then holding the glass particles for 1 hour in an electric furnace set at a predetermined temperature, and measuring the temperature at which crystals were precipitated.

For the glass of Example 1, the liquidus viscosity was measured. The liquidus viscosity was measured by measuring a temperature-viscosity curve according to an inner cylinder rotation method and calculating the viscosity at the liquidus temperature.

For the glass of Example 1, the fracture toughness value K_{IC} (MPa m^{0.5}) was measured. The fracture toughness value K_{IC} was measured using a single-edge-precracked-beam method (SEPB method) as defined in JIS R1607:2015 “Testing methods for fracture toughness of fine ceramics at room temperature”.

For the glass of Example 1, the devitrification suppression parameter value A was calculated using Formula (1) based on the composition.

The number of oxides contained in the glass of Example 1 and present in a content of 0.5% or more (that is, the number of components, N) was calculated.

For the glass of Example 1, the transmittance for light with a wavelength of 350 nm and the transmittance for light with a wavelength of 1050 nm were measured. The transmittance was measured by measuring a spectral transmittance curve using an ultraviolet-visible spectrophotometer (UH4150 type, manufactured by Hitachi High-Tech Corporation).

The measurement results and the calculation results are shown in Table 1.

### Examples 2 to 47

In Examples 2 to 47, a glass was manufactured in the same manner as in Example 1 except that each composition of the glass was as shown in Table 1. The measurement results and calculation results of each example are shown in Tables 1 to 5.

### Evaluation

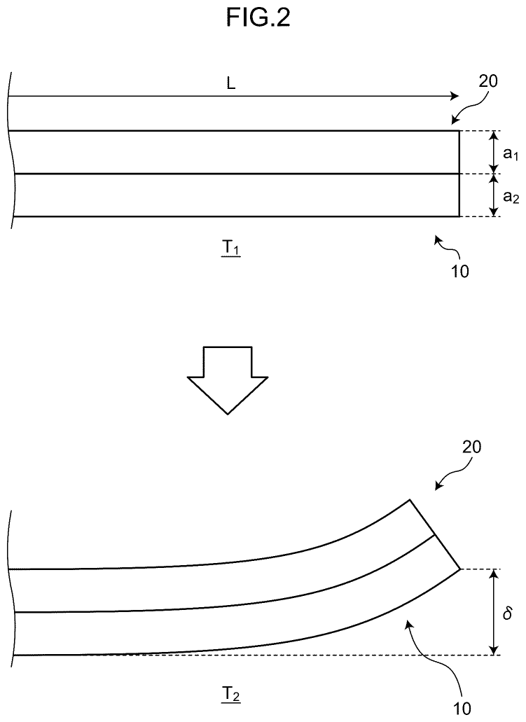

For the glass of each example, deflection and manufacturability were determined. The deflection evaluation was carried out on the basis of the Bi-Metal warpage calculation defined in the document S. Timoshenko, “Analysis of Bi-Metal Thermostats” J. Opt. Soc. Am. 11 (1925) 233. FIG. 2 is a schematic diagram for explaining the deflection evaluation. Here, as illustrated in FIG. 2, the amount of warpage 6 is defined as an amount of displacement of the end portion of the glass 10 in either of the vertical up direction or the vertical down direction with the center of the second surface 14 as a height reference, in a process of molding and bonding a semiconductor substrate with a resin to the first surface 12 side of the glass 10 processed into the shape of FIG. 1, the displacement being caused when cooling from a high temperature state of 200° C. to a low temperature of 20° C. is performed. Specifically, the amount of warpage 6 is calculated by Formula (4).

$$δ = \frac{6 {L}^{2} ( {α}_{2} - {α}_{1} ) ( {T}_{2} - {T}_{1} ) {( 1 + m )}^{2}}{8 h [ 3 {( 1 + m )}^{2} + ( 1 + mn ) \{ {m}^{2} + {( mn )}^{- 1} \} ]} \qquad ( 4 )$$

Here, as illustrated in FIG. 2, L is a length in a warpage direction (lateral direction in FIG. 2) of the glass 10, α₁ is a coefficient of linear thermal expansion of the resin substrate 20, α₂ is a coefficient of linear thermal expansion of the glass 10, T₂ is a temperature after cooling (here, 20° C.), and T₁ is a temperature before cooling (here, 200° C.). In addition, m is a₁/a₂, h is A₁+a₂, and n is Y₁/Y₂. Here, α₁ is the thickness of the resin substrate 20, a₂ is the thickness of the glass 10, Y₁ is the Young's modulus of the resin substrate 20, and Y₂ is the Young's modulus of the glass 10. In the deflection evaluation, the thickness of the resin substrate 20 to be bonded to the glass 10 was assumed to be 0.3 mm and the Young's modulus thereof was assumed to be 31.5 GPa, in consideration of semiconductor mounting. Assuming four patterns of coefficient of linear thermal expansion: 3.0 ppm/° C., 4.0 ppm/° C., 5.0 ppm/° C., and 5.5 ppm/° C., each amount of warpage 6 was calculated in a case where the thickness of the glass 10 was 0.7 mm and the length L=300 mm. In the determination of deflection, a case where the average of the absolute values of the calculated values 6 of the four patterns was less than 1.672 mm was evaluated as “O”, a case where the average was less than 1.60 mm was evaluated as “⊚”, and a case where the average was 1.672 mm or more was evaluated as “X”. In addition, the manufacturability refers to ease of manufacturing, and a case where the liquidus temperature was less than 1400° C. was evaluated as “◯”, and a case where the liquidus temperature was 1400° C. or higher was evaluated as “X”.

As shown in Tables 1 and 2, in Examples 1 to 36 in which the Young's modulus is 95 GPa or more, the coefficient of linear thermal expansion is 5.5 ppm/° C. or less, and the devitrification suppression parameter value A is 6.0 or more, the deflection determination and the manufacturability determination are “O” to “0”, and it can be seen that manufacturing can be easily performed while deflection is suppressed. On the other hand, in Examples 37 to 47, which are comparative examples, since a devitrification suppression parameter value A of 6.0 or more is not satisfied, the manufacturability determination is “X”, and it can be seen that manufacturing cannot be easily performed. In Examples 37, 42, 43, and 45 to 48, the deflection determination was also “x”.

According to the present invention, manufacturing can be facilitated while deflection is suppressed.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A glass having a Young's modulus of 95 GPa or more, a coefficient of linear thermal expansion of 5.5 ppm/° C. or less, and a devitrification suppression parameter value A represented by Formula (1) of 6.0 or more,
$$A = {\{ N \cdot ( - R \sum [ {R}_{x} {O}_{y} ] ln [ {R}_{x} {O}_{y} ] ) \}}^{0.4} \qquad ( 1 )$$
wherein N is a number of oxides present in a content of 0.5% or more in terms of mol % on an oxide basis, among oxides contained in the glass,
R is a gas constant, and
[RₓO_{y}] is a content of oxide RₓO_{y} contained in the glass in terms of mol % on an oxide basis.

2. The glass according to claim 1, wherein a content of Ta₂O₅ in terms of mol % on an oxide basis is less than 0.5%.

3. The glass according to claim 2, wherein the Young's modulus is 105 GPa or more, and the coefficient of linear thermal expansion is 5.1 ppm/° C. or less.

4. The glass according to claim 1, wherein the content of Ta₂O₅ in terms of mol % on an oxide basis is 0.5% or more, and the devitrification suppression parameter value A is 6.4 or more.

5. The glass according to claim 1, comprising:
SiO₂: 35% to 60%,
Al₂O₃: 6% to 20%, and
MgO: 13% to 28%,
as expressed in mol % on an oxide basis.

6. The glass according to claim 1, wherein a transmittance of light with a wavelength of 350 nm at a thickness of 0.7 mm is 30% or more.

7. The glass according to claim 1, wherein a transmittance of light with a wavelength of 1050 nm at a thickness of 0.7 mm is 80% or more.

8. The glass according to claim 1, wherein N is 8 or more.

9. The glass according to claim 1, which is used as a substrate.

10. The glass according to claim 9, which is used in manufacture of at least one of a fan out wafer level package or a fan out panel level package.
